(19) United States
(12) Patent Application Publication
(10) Pub. No.: US 2023/0084088 A1
(43) Pub. Date: Mar. 16, 2023

(54) METHODS AND SYSTEMS FOR PHOTOPATTERNING AND MINIATURIZATION

(71) Applicant: Duke University, Durham, NC (US)

(72) Inventors: Xin Song, Durham, NC (US); John Reif, Durham, NC (US)

(21) Appl. No.: 17/797,765

(22) PCT Filed: Feb. 5, 2021
(86) PCT No.: PCT/US2021/016830

§ 371 Date: Aug. 5, 2022

Related U.S. Application Data
(60) Provisional application No. 62/970,311, filed on Feb. 5, 2020.

(51) Int. Cl. G03F 7/20; G03F 7/38

(52) U.S. Cl. CPC G03F 7/2047; G03F 7/2051; G03F 7/38; G03F 7/2008; G03F 7/70875; G03F 7/70008; G03F 7/70525

(57) ABSTRACT

Methods and systems for photopatterning and miniaturization. In some examples, a method for patterning a substrate includes irradiating a pattern onto the substrate with ultraviolet light and heating the substrate, causing the substrate and the pattern to shrink in at least one dimension to form a miniaturized pattern on the substrate. In some examples, a system for patterning a substrate includes an ultraviolet light source, a heater, and a controller configured for irradiating a pattern onto the substrate with ultraviolet light and heating the substrate, causing the substrate and the pattern to shrink in at least one dimension to form a miniaturized pattern on the substrate.

### PRIORITY CLAIM

This application claims the benefit of U.S. Provisional Patent Application Ser. No. 62/970,311, filed Feb. 5, 2020, the disclosure of which is incorporated herein by reference in its entirety.

### STATEMENT OF GOVERNMENT INTEREST

This invention was made with government support under Federal Grant nos. CCF 1617791 and CCF 1813805 awarded by the National Science Foundation. The government has certain rights in the invention.

### TECHNICAL FIELD

The subject matter described herein relates generally to patterning a substrate. More particularly, the subject matter described herein relates to photopatterning of a substrate and miniaturization of the substrate and the pattern.

### BACKGROUND

There are a variety of methods used for rapid prototyping of submicron scale features and devices. The technique of shrink-based pattern miniaturization is attractive because it can leverage a single mold to replicate and miniaturize patterns to much smaller scales, enabling a top-down approach to large-area micro/nanofabrication with substantially reduced processing time, cost, and complexity. For example, pre-stressed thermoplastics such as polystyrene (PS) and polyolefin (PO) films can be used as convenient substrates for pattern shrinkage. Heating above the glass transition temperature can trigger the polymer shape recovery and result in miniaturization of surface patterned features. In particular, PS is a low-cost commodity thermoplastic polymer widely used for fabricating microsystems such as microfluidic devices owing to its attractive properties including biocompatibility, moldability, and optical transparency. However, conventional patterning techniques still typically involve expensive equipment, harsh chemicals, and/or slow multi-step processes. It remains challenging to inexpensively and rapidly pattern, replicate, and miniaturize microfeatures on shrinkable materials with high resolution, yield, and reproducibility under ambient conditions. Hence, there is an ongoing need for improved methods of shrink lithography.

### SUMMARY

This specification describes methods and systems for photopatterning and miniaturization. In some examples, a method for patterning a substrate includes irradiating a pattern onto the substrate with ultraviolet light and heating the substrate, causing the substrate and the pattern to shrink in at least one dimension to form a miniaturized pattern on the substrate. In some examples, a system for patterning a substrate includes an ultraviolet light source, a heater, and a controller configured for irradiating a pattern onto the substrate with ultraviolet light and heating the substrate, causing the substrate and the pattern to shrink in at least one dimension to form a miniaturized pattern on the substrate.

### BRIEF DESCRIPTION OF THE DRAWINGS

FIGS. 1A-1F illustrate the experimental setup and procedure for UV-micropatterned miniaturization;

FIGS. 2A-2C show examples of UV-micropatterning and miniaturization on PS and PO surfaces;

FIGS. 2D and 2E show examples of UV-micropatterning on a Flexdym™ polymer surface;

FIGS. 3A-3D illustrates the effect of varying UV exposure time and proximity on PS micropatterning and miniaturization;

FIGS. 4A-4D illustrate examples of UV-micropatterned miniaturization using TEM grids with different mesh patterns as photomasks;

FIG. 5 is a flow diagram of a method for photopatterning and miniaturization of a substrate; and

FIG. 6 is a block diagram of a system for patterning a substrate.

### DETAILED DESCRIPTION

This specification describes methods and systems for photopatterning and miniaturization. The methods and systems are described with reference to a study that was performed on example implementations of the methods and systems.

Soft lithography^{[1]} enables researchers to rapidly pattern functional surfaces and fabricate devices at the submicron scale without sophisticated processes or expensive equipment required by conventional micro/nanofabrication techniques such as photolithography and electron beam lithography. However, the patterning feature size and resolution in soft lithography are ultimately determined and constrained by the master molds used for fabricating stamps.

In contrast, the technique of shrink-based pattern miniaturization^{[2]} is attractive because it can leverage a single mold to replicate and miniaturize patterns to much smaller scales, enabling a promising top-down approach to large-area micro/nanofabrication with substantially reduced processing time, cost, and complexity. For example, hydrogels have been specifically formulated to replicate and shrink 2D or 3D patterns.^{[3]} However, uniform shrinkage of hydrogels depends on elaborately controlled conditions and typically requires dehydration for hours at elevated temperatures, limiting the miniaturization efficiency and reproducibility.

Alternatively, prestressed thermoplastics such as polystyrene (PS) and polyolefin (PO) films can be used as convenient substrates for pattern shrinkage. Heating above the glass transition temperature can trigger the polymer shape recovery and result in miniaturization of surface patterned features.^{[2]} In particular, PS is a low-cost commodity thermoplastic polymer widely used for fabricating microsystems such as microfluidic devices owing to its attractive properties including biocompatibility, moldability, and optical transparency.^{[4]}

Whitesides and coauthors^{[5]} demonstrated high-aspect-ratio microstructure shrinkage on patterned PS films. Khine and coauthors^{[6]} used off-the-shelf PS sheets known as “Shrinky Dinks” to miniaturize laser-jet printed patterns for microfluidics prototyping. In order to generate micropatterns/structures on PS substrates, prior methods relied on hot embossing,^{[7]} PDMS replica molding,^{[8]} solvent-assisted embossing^{[9]} or swelling,^{[10]} reactive ion etching,^{[5]} laser ablation,^{[11]} or mechanical engraving.^{[12]} However, these patterning techniques usually involve expensive equipment, harsh chemicals, or slow multi-step processes, making it difficult to inexpensively and reproducibly achieve rapid micropatterning on PS under ambient conditions.

Among these techniques, micropatterning based on temporary deformation of thermoplastic surface (e.g., via embossing or imprinting) may not work well with shrink-induced pattern miniaturization because the patterns can easily deform or completely vanish due to the material reflow during the thermal shrinking process.^{[13]} Subtractive patterning by removal of parts from the bulk material^{[5,11,12,14]} (e.g., via physical/chemical etching) or additive patterning by material deposition^{[15]} (e.g., via contact printing) may be utilized for shrink-intended micropatterning such that the patterned features remain intact in miniaturized form after substrate shrinkage. However, the reliance on special equipment and chemicals still makes most of these prior patterning methods inefficient and unsuitable to allow rapid microfabrication and prototyping in a standard laboratory where budget, resource, or expertise might be limited. In this work, we report the discovery and characterization of a much simpler and cost-efficient method for quickly generating shrinkable micropatterns/structures on commodity prestressed thermoplastic films, enabling a novel pattern miniaturization technique which we term UV-micropatterned miniaturization. Compared to UV patterning on flat polydimethylsiloxane stamps,^{[16]} our combined method of micropatterning and in situ pattern miniaturization on shrinkable thermoplastics requires only a compact UV pencil lamp and a low-cost toaster oven as equipment, and no chemical reagents or laborious training/preparation are needed. The entire micropatterning and shrinking process can be done on benchtop within minutes to fabricate miniaturized micropatterns/structures with high yield, fidelity, and reproducibility.

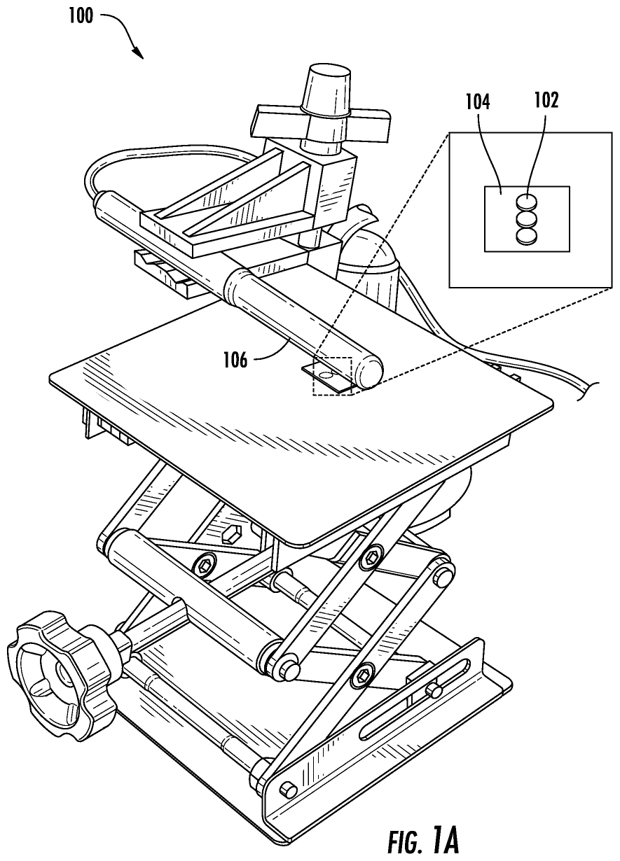

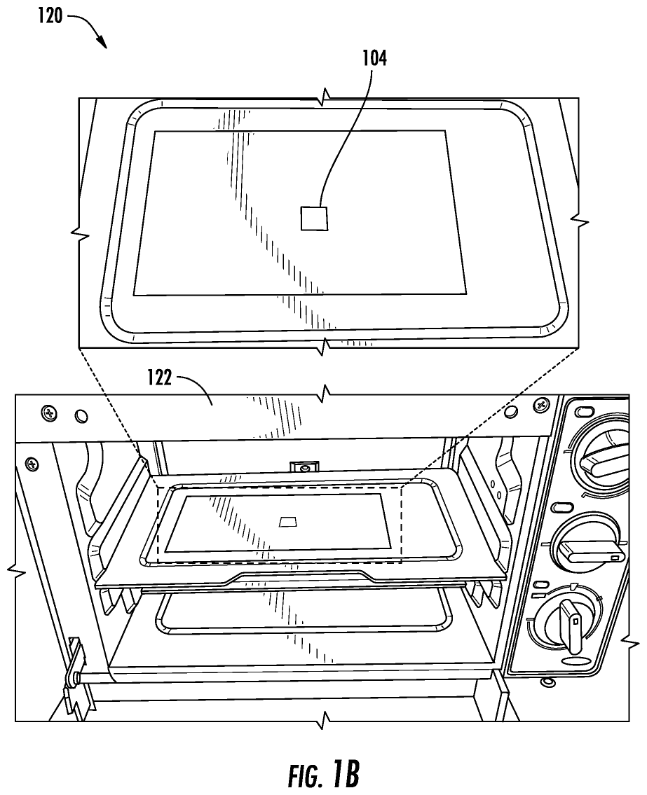

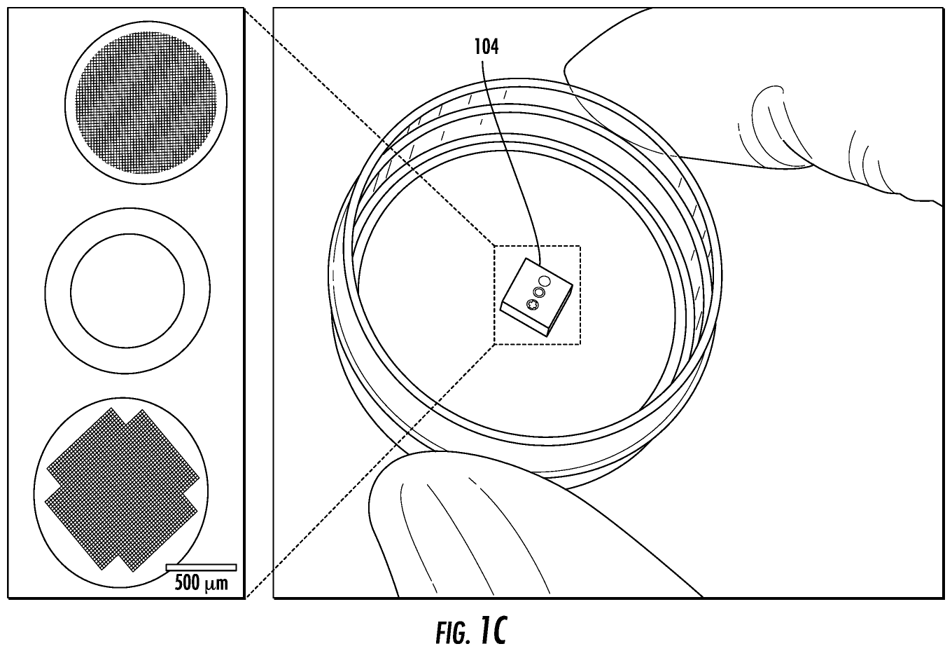

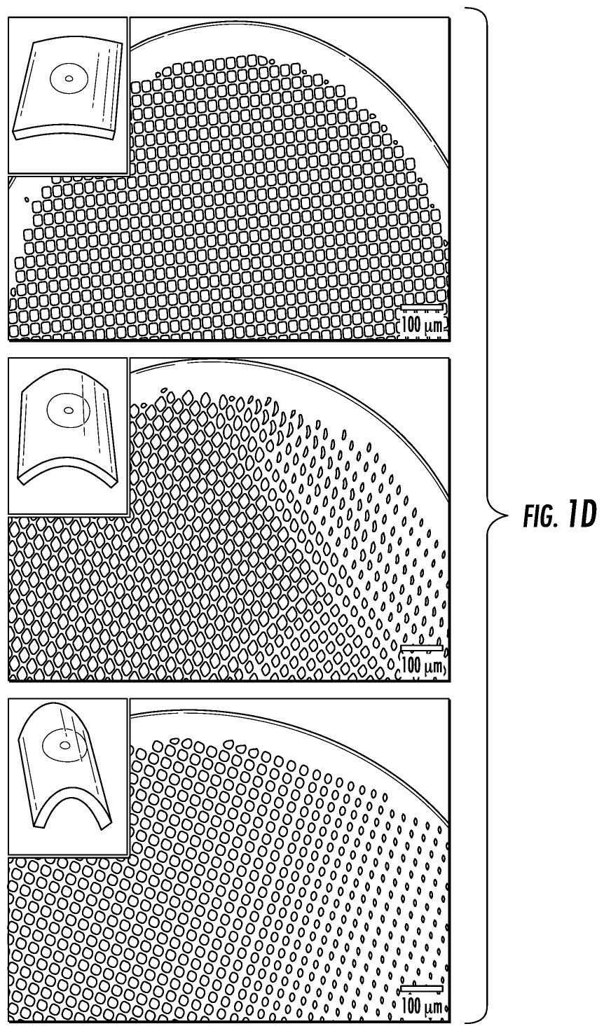

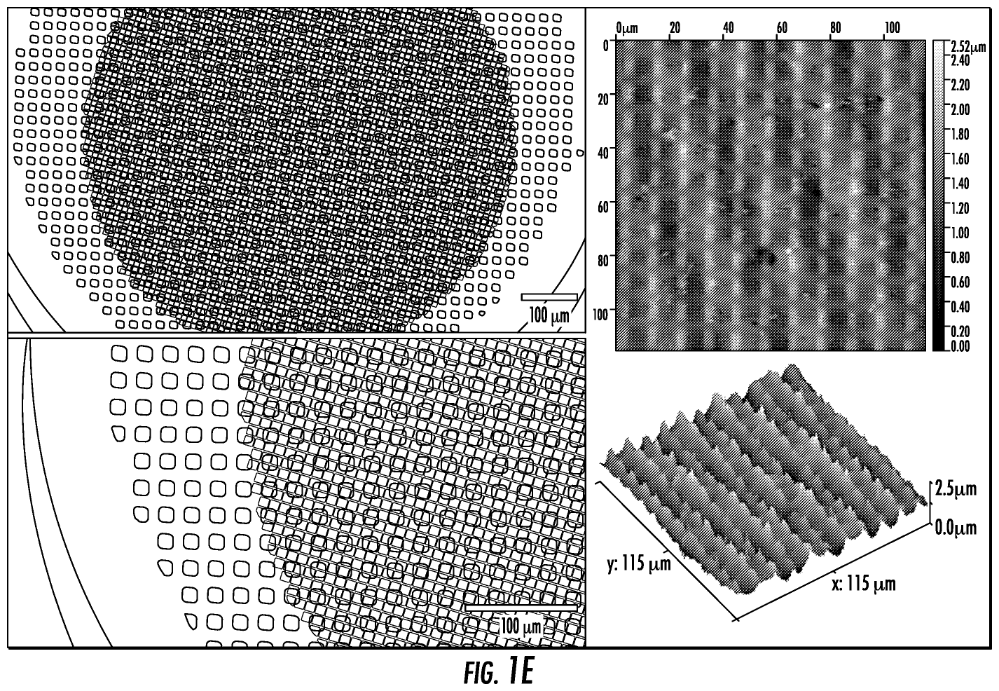

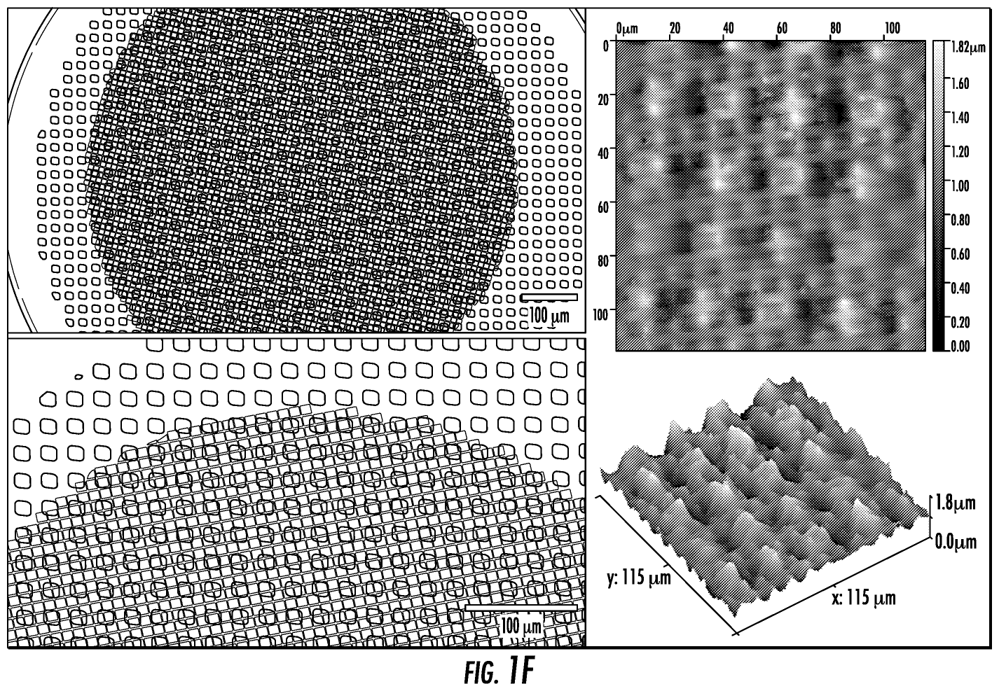

FIGS. 1A-1E illustrate the experimental setup and procedure for UV-micropatterned miniaturization. FIG. 1A shows an example system 100 for irradiating a substrate.

TEM grids 102 with different mesh patterns serving as photomasks were placed on a small piece of PS shrink film 104 (Grafix® clear shrink film). The sample surface was then exposed to UV emitted by a shortwave UV pencil lamp 106 (Spectroline® 11SC-1, 254 nm) at a short distance for a few minutes.

During this process, photochemical reactions induced by shortwave UV led to polymer chain scission and oxidation at the irradiated regions, resulting in permanent pattern transfer of the microfeatures from the TEM grid onto the film with high efficiency and resolution. This UV-patterning step was conducted in a standard fume hood with the presence of air under ambient conditions.

FIG. 1B shows an example system 120 for heating a substrate. After irradiation, the PS film was baked in a toaster oven 122 at 160° C. for approximately 1.5 minutes to induce its complete biaxial shrinkage. Finally, the miniaturized micropatterns appearing on the shrunken film surface were characterized by optical microscopy and atomic force microscopy (AFM). FIG. 1C shows that the shrunken PS film 104 revealed the miniaturized micropatterns on its surface.

Our technique also allows easy fabrication of miniaturized microstructures/patterns on surfaces with different curvatures by quickly bending the micropatterned shrunken film while it remains flexible before cooling down. FIG. 1D shows UV-micropatterned miniaturization on curved PS surfaces. UV irradiation lasted for 3 minutes at a distance of 3 mm. After baking in a toaster oven, the shrunken micropatterned film was quickly bent into different curvatures before cooling down. Scale bars are 100 μm.

Furthermore, simple sequential UV exposures enable facile prototyping of sophisticated 3D microtopography with miniaturized, multi-scale, multi-dimensional microstructures and micropatterns. FIGS. 1E-1F show sequential-UV-micropatterned miniaturization of complex 3D microtopography. FIG. 1E shows that, during two sequential UV exposures, the shrink film surface was first masked by a TEM grid with large-square mesh (cat. 0400-Cu) and then by a grid with small-square mesh (cat. T1000-Cu). FIG. 1F shows sequential UV exposures with the above order of masks reversed. The UV exposure with each mask lasted for 1.5 min at a distance of 3 mm. Scale bars in optical micrographs are 100 μm.

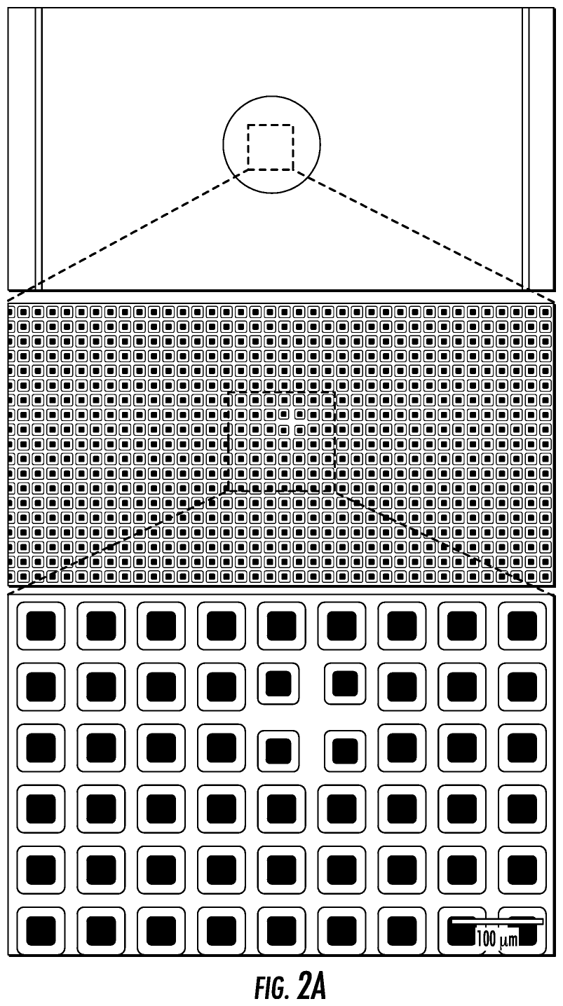

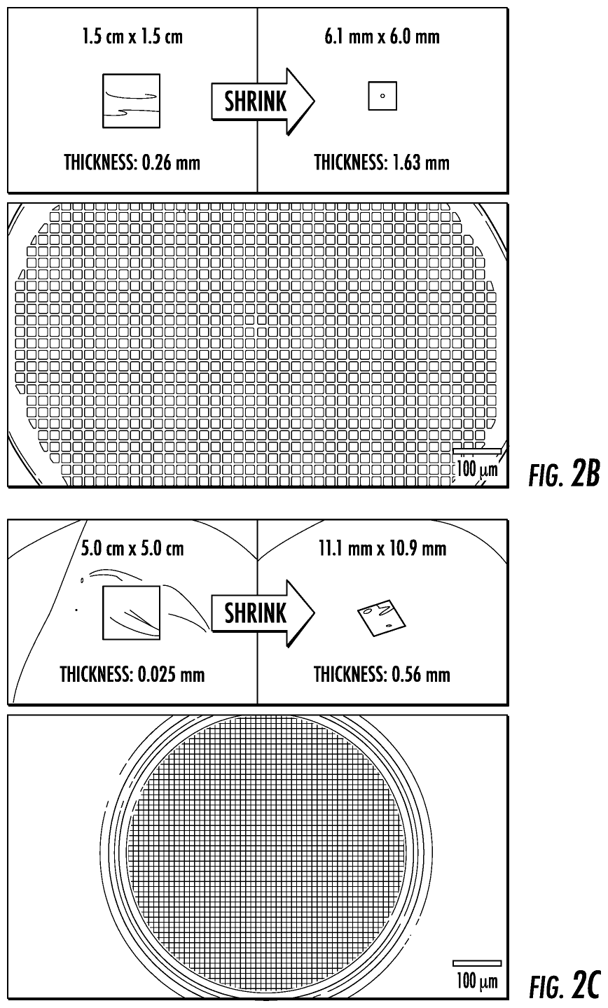

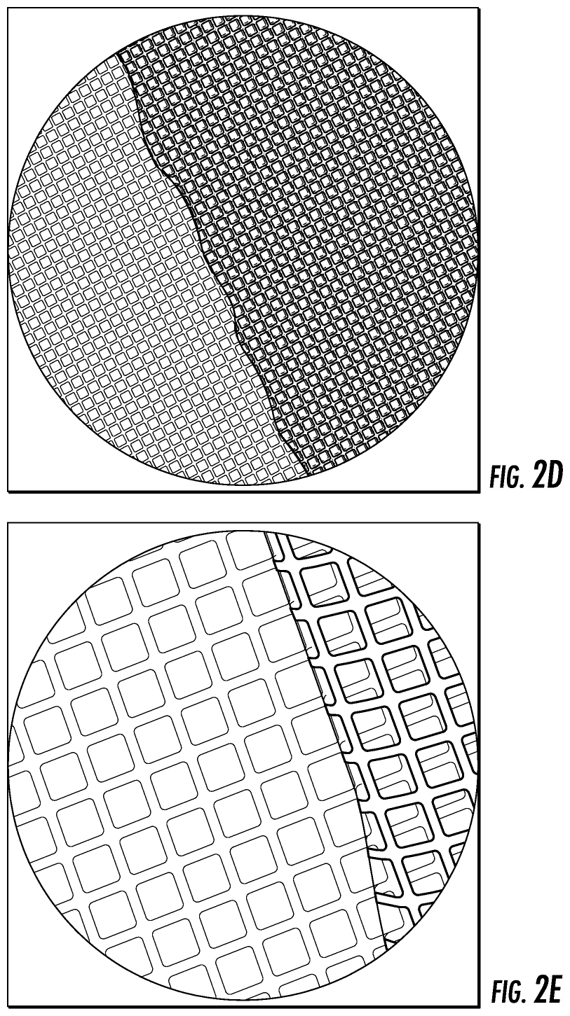

FIGS. 2A-2C show examples of UV-micropatterning and miniaturization on PS and PO surfaces. FIG. 2A shows a master pattern from a 400-mesh grid with square holes measuring 30×30 μm. FIG. 2B shows UV-micropatterned miniaturization on PS film. FIG. 2C shows UV-micropatterned miniaturization on PO film. Scale bars are 100 μm.

Interestingly, microfeatures transferred from the photomask (e.g., as shown in FIG. 2A) were not visible on the PS surface until they emerged in the miniaturized form after film shrinkage. To explain such a phenomenon, we compared the thickness and planar dimensions of the PS film before and after its complete shrinkage (FIG. 2B) and noticed that the total volume of the thermoplastic sample was roughly conserved during the shrinkage.

Therefore, we conjecture that the planar shrinkage of PS film (˜84% reduction in pattern surface area) may have simultaneously resulted in a significant increase in the micropatterns' feature height, leading to the clearly visible micropatterns with pronounced depth profiles after the biaxial miniaturization process. Our efficient UV-micropatterned miniaturization technique also worked effectively with PO shrink films^{[15,17]} (Sealed Air Cryovac® D955, 100 gauge), generating miniaturized micropatterns with a remarkable ˜95% reduction in pattern surface area (e.g., as shown in FIG. 2C). The lateral shrinkage ratios of both materials showed a small directional bias (<3%), yet it was consistent in multiple shrink tests and was likely due to slightly uneven pre-stretch on the films during the polymer extrusion process in manufacturing.

FIGS. 2D and 2E illustrate an example of UV patterning on Flexdym™. The patterning included 20 minutes of UV exposure at a 3 mm distance. The pattern illustrated was generated using a TEM grid with 19 μm hole and 6 μm bar. The UV micropatterning led to visible patterns on Flexdym surface starting ˜5 minutes. The patterning process can be further accelerated by reducing the exposure distance.

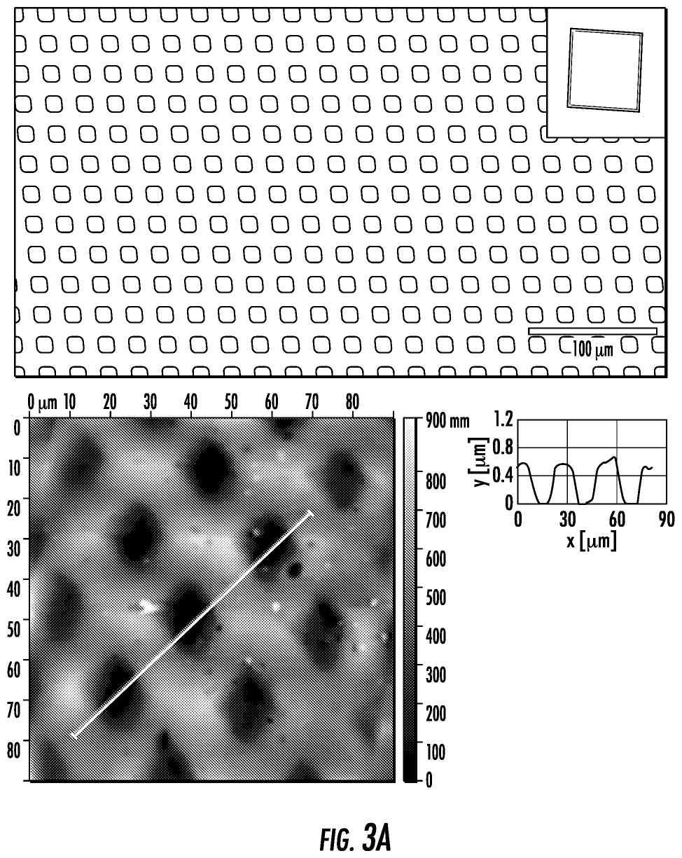

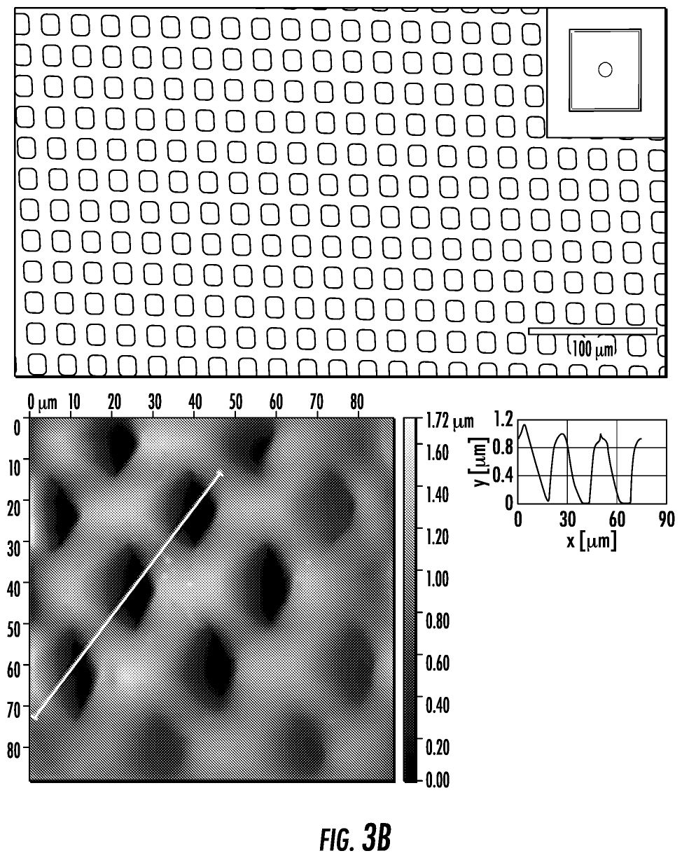

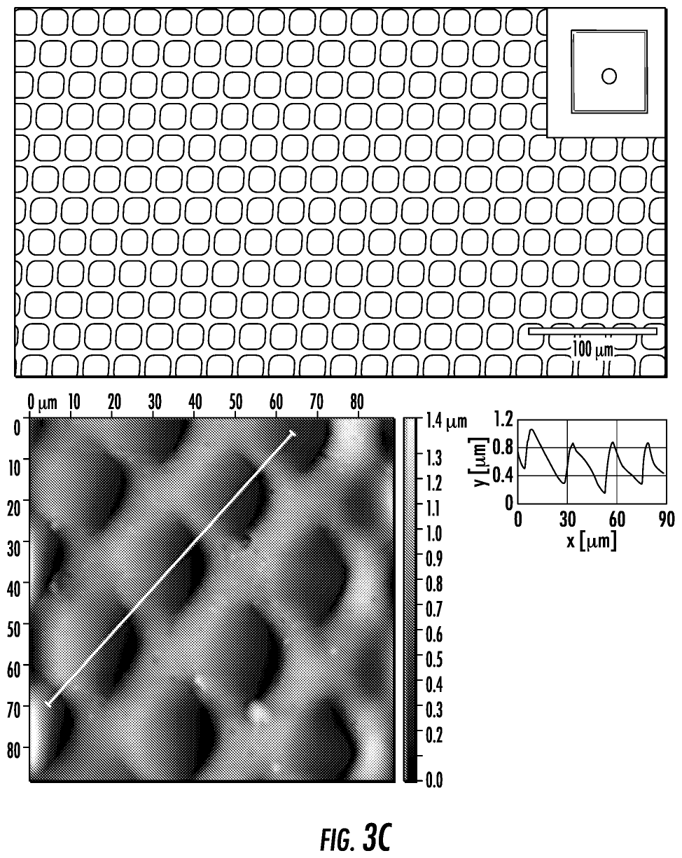

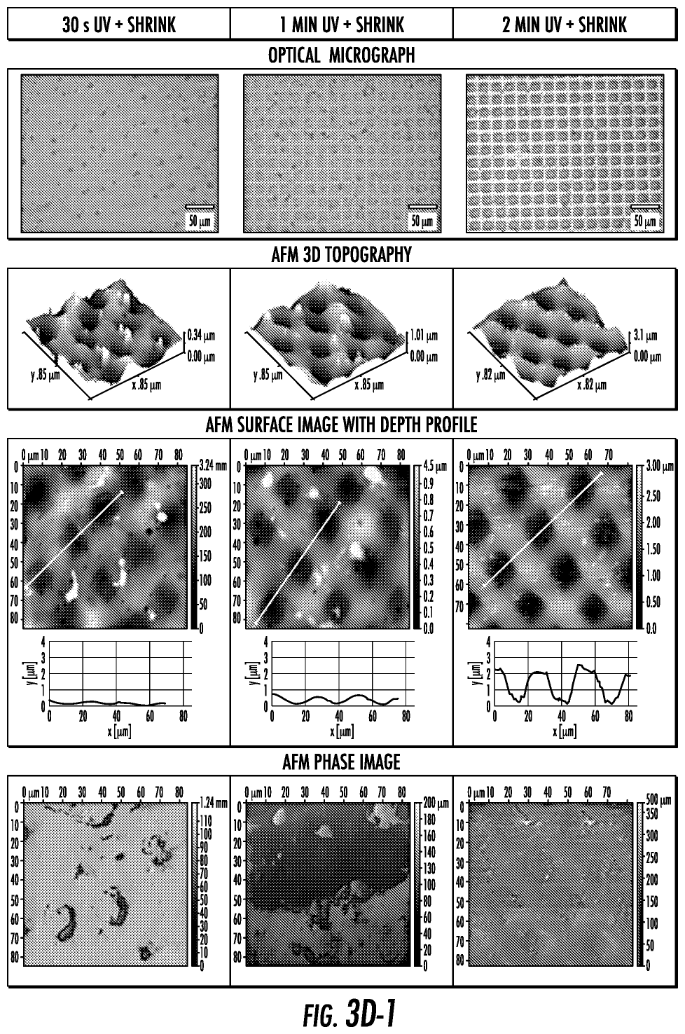

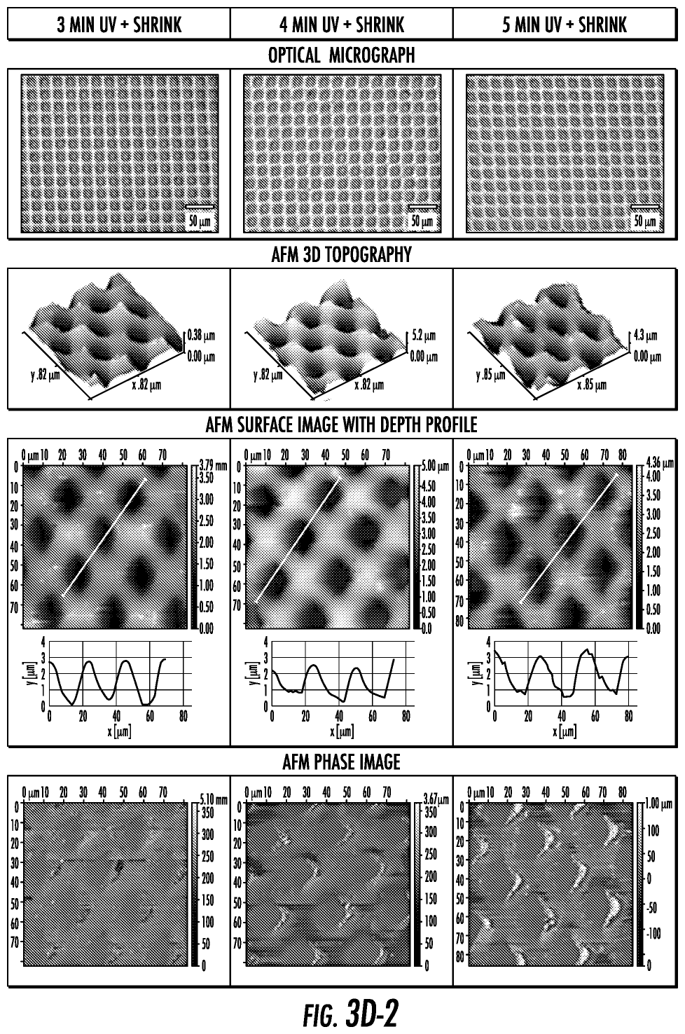

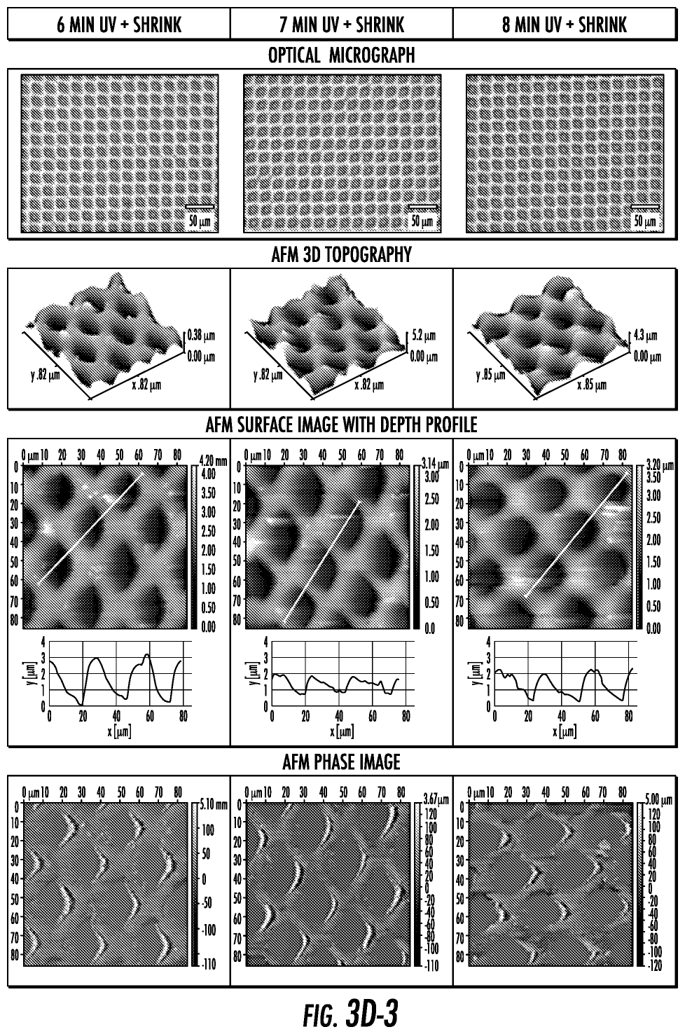

FIG. 3D illustrates the effect of varying UV exposure time on PS micropatterning and miniaturization. The same 400-square-mesh copper grid was repeatedly reused as the photomask across nine experiments. Some miniaturized squares appeared as rhombi due to a slight directional bias in film shrinkage. Signal overshoot at the microfeature edges in AFM phase images was likely due to imaging artifacts.^{[18]} Scale bars in optical micrographs are 50 μm.

To characterize the effect of UV irradiation on the micropatterned surface topography, we varied the time and distance of UV exposures on PS film covered by a photomask. As shown in FIG. 3D, UV irradiation (fixed at a distance of 3 mm) for as short as 30 seconds could transfer some micropatterns onto the PS surface, although the feature details were hardly discernable due to the low patterning depth.

Further increased UV exposure time led to miniaturized grid patterns with well-defined microfeatures reaching a few microns in depth after the film shrinkage. However, compared to shorter exposures, UV irradiation beyond 4 to 5 minutes appeared to have a smoothing effect on the miniaturized micropattern topography (manifested as gradually enlarged square holes with a decrease in feature depth).

Additionally, the shrunken PS surface corresponding to longer exposures exhibited a more fluidic appearance under the optical microscope. These observed changes in pattern surface appearance were likely due to the combined effect of excessive diffusing reactive oxygen species generated during extended UV irradiations and the shape-memory effect of thermoplastics (i.e., the reorganization of cross-linked polymer chains during thermal shrinkage).

As expected, variations of the UV exposure distance had a similar effect on the micropatterned topography post shrinkage. Overall, we found that 3 minutes of UV exposure at a distance of 3 mm appeared to achieve the best micropatterning and miniaturization quality on PS in terms of the uniformity of patterning and faithful replication and shrinkage of microfeatures from the original photomask.

FIGS. 3A-3C illustrate the effect of varying UV exposure distance on PS micropatterning and miniaturization. FIG. 3A shows the result at a 10 mm distance. FIG. 3B shows the result at a 5 mm distance. FIG. 3C shows the result at a 1 mm distance. As shown in the insets, shorter exposure distance led to more evident roughening at the irradiated region on thermoplastic surface. Scale bars in optical micrographs are 100 μm.

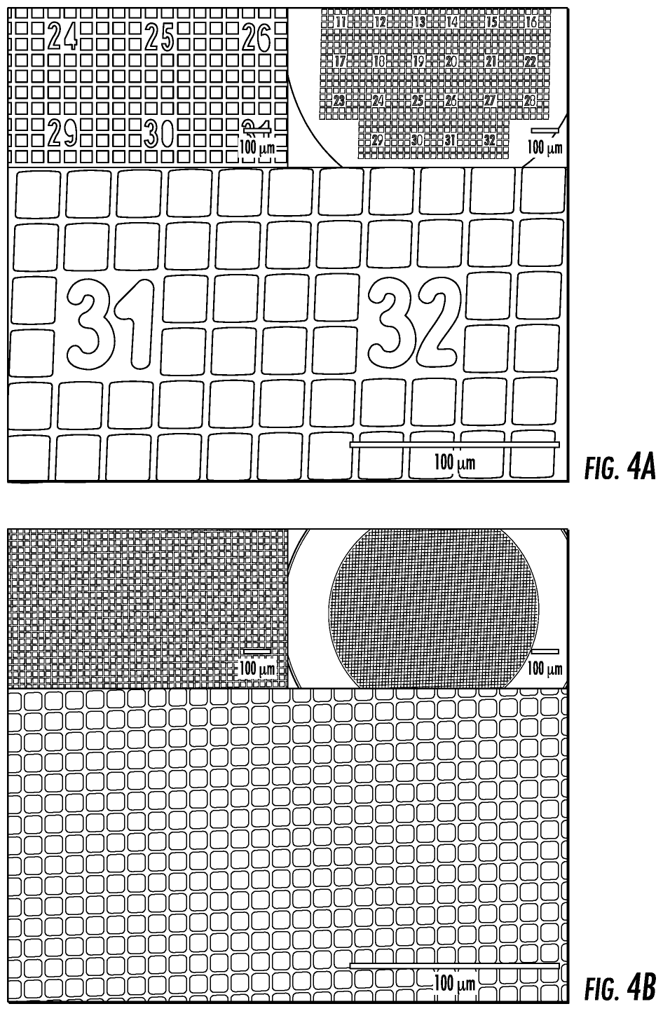

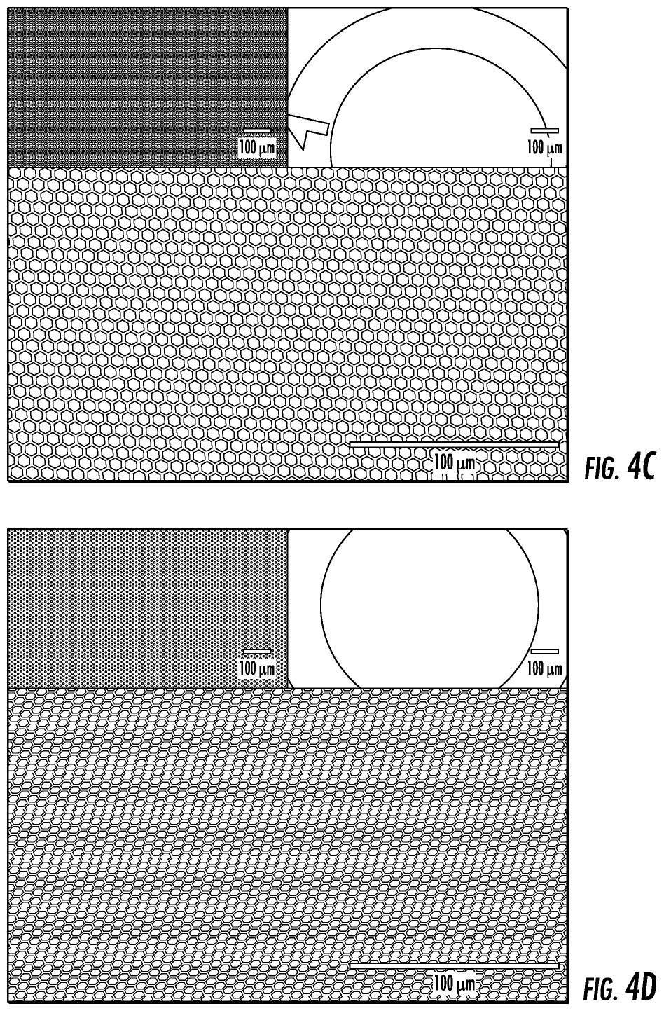

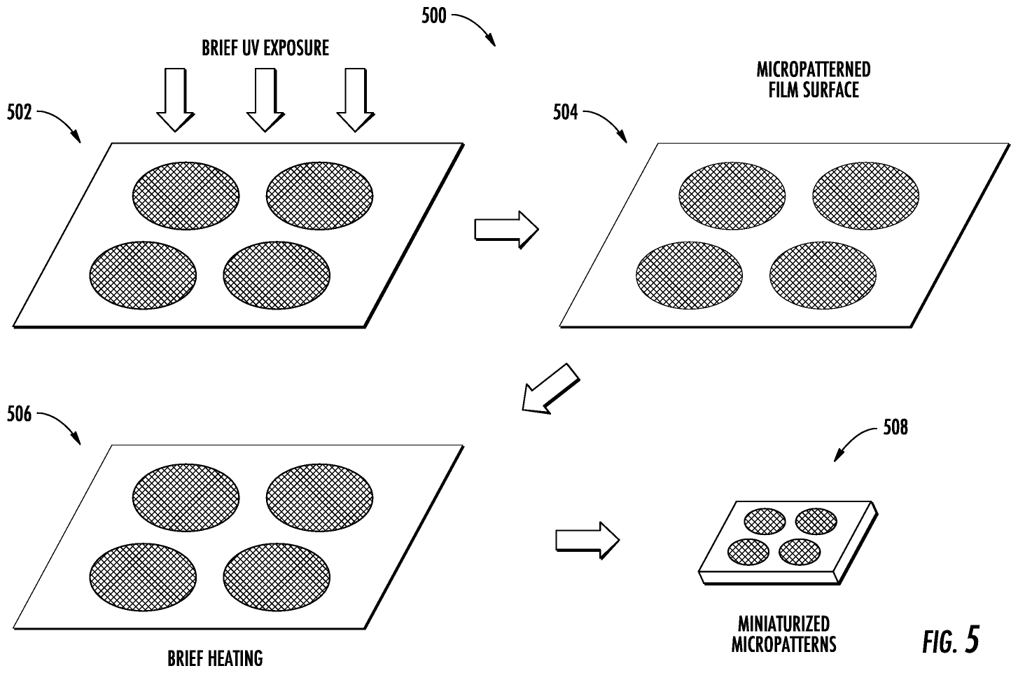

A variety of miniaturized micropatterns were fabricated using TEM grids with different mesh patterns (numbers, squares, hexagons, and circles) and hole sizes ranging from approximately 5 μm to 50 μm. FIGS. 4A-4D illustrate examples of UV-micropatterned miniaturization using TEM grids with different mesh patterns as photomasks. FIG. 4A shows a 400-mesh finder grid (G400F1-Cu, 47 μm holes). FIG. 4B shows a 1000-mesh square grid (T1000-Cu, 19 μm holes). FIG. 4C shows a 1500-mesh hexagonal grid (G1500HH-Cu, 10.5 μm holes). FIG. 4D shows a 2000-mesh circular grid (G2000HA-Cu, 6.5 μm holes). Shown in each panel are optical micrographs of the mesh pattern on TEM grid, the replicated and miniaturized pattern on shrunken PS surface, and a magnified view of the miniaturized pattern on PS, respectively. Scale bars are 100 μm.

Since the micropatterns remained visible and intact in the miniaturized form even after months of storage under ambient conditions, we conjecture that the high-fidelity micropatterning was achieved by UV-induced photochemical reactions leading to permanent topographical modifications on the exposed thermoplastic film surface. Indeed, previous work^{[19]} investigated the effect of shortwave UV irradiation on polymers under ambient conditions with the presence of air/oxygen. Specifically, the 253.7 nm and 184.9 nm UV emitted from low-pressure mercury-vapor discharge lamps were found to excite the molecular oxygen in situ to form atomic oxygen and ozone.

These reactive gaseous species produced by the combined effect of UV-ozone treatment significantly increased the surface energy of materials including PS and led to polymer chain scission and oxidation at the irradiated regions. In our study, the pencil lamp emits 254 nm shortwave UV radiation with an average intensity of 4500 μW cm⁻² measured at 2.54 cm distance (data from product literature), and its emission spectrum contains a range of other wavelengths that possibly include 185 nm.

As shown in AFM phase images (FIG. 3D), the color difference between the exposed and unexposed regions possibly suggests a change in the PS surface properties after UV micropatterning. For instance, the different appearance of surface wrinkling at the exposed regions may signify a change of surface modulus on the PS film.

Furthermore, we noticed that the extended UV irradiation led to increased roughening on the exposed PS surface, which appears consistent with the prior observation that prolonged UV-ozone treatment tends to form a thin layer of low-molecular weight oxidized material on PS surface.^{[19]} We also tested micropatterning with a handheld UV lamp (UVP® UVGL-15, 365/254 nm, 4 Watt), but we did not observe noticeable pattern formation. These observations suggest that the specific wavelength and intensity of UV radiation from the shortwave UV pencil lamp played an important role in rapid micropatterning on thermoplastics.

As observed in AFM cross-sectional depth profiles (Error! Reference source not found.D), UV exposures longer than 2 minutes appeared to result in some degree of tapering at the edges of miniaturized microfeatures. On one hand, it is possible that the reactive oxygen species generated during the micropatterning process diffused under the edges of the TEM grid bars (which were supposed to protect select areas on the film from UV exposure) and led to unintended molecular scissions contributing to the tapering at the top edges of shrunken microfeatures. Such a tapering effect can be minimized by improving the contact between the mask and the film surface and by optimizing the amount of incident UV irradiation.

On the other hand, the reorganization of cross-linked polymer chains during thermal shrinkage may inevitably smooth out some micropatterned features with steep sidewalls and result in the observed tapering effect. As a characteristic of shape-memory polymers, such an effect is difficult to obviate but may be lessened by fine-tuning the thermal shrinking process.^{[20]}

TABLE 1
Summary of potential defects from UV-micropatterned miniaturization
or intrinsic to shrink film material/manufacturing.

| | Type of Defects | | | |
|---|---|---|---|---|
| | | | Surface | |
| Source of Defects | Point Defects | Line Defects | Inhomogeneities | Dimension Variations |
| Introduced during | Residual dirt | Surface scratches | Uneven patterning | Uneven miniaturization |
| UV-micropatterned | particles on | (handling) | depth or direction | (incomplete thermal |
| miniaturization | mask or | | (imperfect mask- | shrinkage); |
| | substrate | | substrate contact; UV | Edge tapering of steep |
| | | | projection variation | features (prolonged UV |
| | | | due to exposure | exposure) |
| | | | geometry) | |
| From shrink film | Embedded | Surface scratches | Surface roughness; | Directional bias in |
| manufacturing or | impurities or | (manufacturing) | Surface wrinkling | shrinkage (unevenly pre- |
| intrinsic to material | air bubbles | | | stressed film); |
| | | | | Edge tapering of steep |
| | | | | features (shape-memory |
| | | | | recovery) |

As summarized in Table 1, potential pattern defects may come from different sources, some of which are intrinsic to the shrink film material or are introduced during the polymer manufacturing process. Most other defects are not inherent to our UV-micropatterned miniaturization technique and can be easily mitigated by (i) improving the surface cleanliness, flatness, and contact between the mask and film and (ii) fine-tuning the incident UV irradiation and the thermal shrinking process.

To enhance the precision and uniformity of UV-micropatterned miniaturization, additional factors to be controlled can include the effect of oxygen and humidity levels. Large-scale and high-throughput manufacturing may be readily enabled by utilizing shortwave UV sources capable of delivering uniform irradiation over large areas. Higher amounts of shrinkage may be achieved via recursive cycles of micropattern miniaturization. However, such an effort may call for heat-shrinkable polymers with high transmission of shortwave UV and may be challenging in terms of the material availability and the potential diminishing resolution during serial pattern transfers. A more viable approach would be using compatible shrink films manufactured with higher amounts of biaxial pre-stress.

FIG. 5 is a flow diagram of a method 500 for photopatterning and miniaturization of a substrate. The substrate can be formed of any appropriate material, e.g., a shrinkable thermoplastic.

The method 500 includes irradiating a pattern onto a substrate with UV light (502), resulting in a micropatterned film surface (504). The pattern can be any appropriate pattern and the method 500 can be used with different patterns. In some examples, irradiating the pattern onto the substrate includes irradiating the substrate through a photomask with the pattern. In some other examples, irradiating the pattern onto the substrate includes modulating the pattern onto the substrate using a programmable digital mirror device (DMD). Irradiating the pattern onto the substrate can include irradiating for a period of time, intensity, and proximity such that photochemical reactions in the substrate result in physically forming the pattern onto the substrate.

The method 500 includes heating the substrate (506), causing the substrate and the pattern to shrink in at least one dimension to form a miniaturized pattern on the substrate (508). Heating the substrate can include heating the substrate for a period of time long enough to cause biaxial shrinkage of the substrate. In some examples, heating the substrate includes heating the substrate in an oven. In general, the oven can be any appropriate device for heating the substrate to a temperature sufficient for shrinkage of the substrate. The oven may include an enclosed space, a heating element, and a controller configured for controlling the heating element to raise the interior temperature of the enclosed space to a specified temperature.

In some examples, the method 500 includes using the substrate and the miniaturized pattern in forming a device. For example, the device can be a microelectronic device, a microfluidic device, a micro-optic device, or a biomedical device, or a combination thereof.

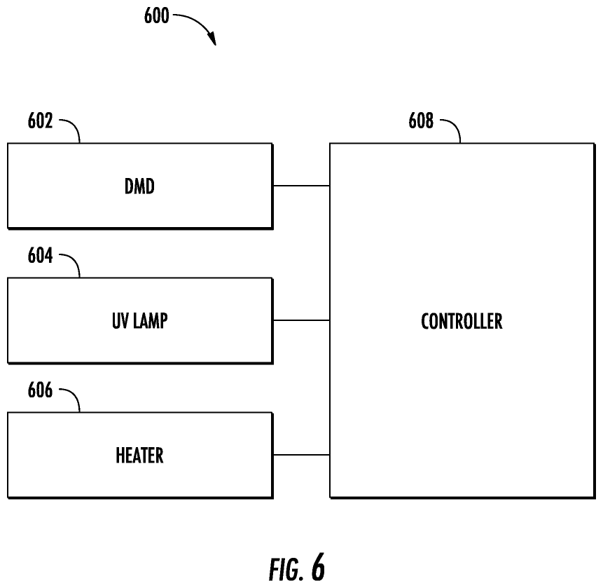

FIG. 6 is a block diagram of an example system 600 for patterning a substrate. The system 600 includes an optional digital mirror device 602, a UV lamp 604, a heater 606 such as an oven, and a controller 608. The controller 608 is configured for irradiating, using the UV lamp 604, a pattern onto the substrate with ultraviolet light and heating the substrate with the heater 606, causing the substrate and the pattern to shrink in at least one dimension to form a miniaturized pattern on the substrate. In some examples, the controller 608 is configured for controlling the DMD 602 to cause the UV lamp 604 to irradiate the pattern onto the substrate. For example, the DMD 602 may be placed between the UV lamp 604 and the substrate, such that controlling the DMD 602 directs the UV light onto the substrate.

In summary, we have reported the discovery and characterization of UV-micropatterned miniaturization—a simple and low-cost technique for rapidly replicating and miniaturizing complex large-area micropatterns on shape-memory polymers such as commodity PS and PO shrink films. The technique enables facile fabrication of miniaturized microfeatures with high yield, fidelity, and reproducibility under ambient conditions without special chemicals or sophisticated equipment.

A variety of micropatterns and multi-dimensional microstructures were fabricated and shrunken to significantly smaller scales on both planar and curved polymer surfaces. Notably, the UV-ozone treated thermoplastic surface is known to have favorable properties including the significant reduction of protein adsorption^{[21]} and enhanced hydrophilicity for cellular attachment.^{[22]} Such an oxidized surface can remain stable and biocompatible over extended periods of time (up to weeks and months as reported in prior studies^{[19,21]}). Therefore, we expect that the miniaturized micropatterned PS chips fabricated by our method could readily be used as functional substrates in downstream biomedical and microfluidic analytical applications.

Due to the effect of UV-ozone chemistry, additional categories of thermoplastic polymers such as polyethylene terephthalate (PET)^{[19]} may also be compatible with UV-micropatterned miniaturization. For example, FIGS. 2D and 2E illustrate an example of UV patterning on Flexdym™ polymer. Flexdym is typically non-shrinkable, so FIGS. 2D and 2E demonstrate UV micropatterning without miniaturization. Although TEM grids were leveraged as simple affordable photomasks for proof-of-concept demonstrations, conventional quartz photomasks allowing high transmission of shortwave UV can be used with our technique to miniaturize complex application-specific micropatterns for engineering functional surfaces with interesting properties.

For example, the ability to generate periodic, multi-scale, multi-dimensional microstructures via sequential UV patterning and to form sophisticated miniaturized microfeatures on both planar and curved surfaces may facilitate facile prototyping of tunable metamaterials.^{[23,24]} Miniaturization of highly ordered, high-density topographical features may enable rapid fabrication of micro-optical/sensing devices with enhanced performance.^{[2]} To facilitate further applications, the miniaturized micropatterns formed on the shrink films may be transferred onto different substrates via conventional techniques such as replica molding.

Accordingly, while the methods and systems have been described herein in reference to specific embodiments, features, and illustrative embodiments, it will be appreciated that the utility of the subject matter is not thus limited, but rather extends to and encompasses numerous other variations, modifications and alternative embodiments, as will suggest themselves to those of ordinary skill in the field of the present subject matter, based on the disclosure herein.

Various combinations and sub-combinations of the structures and features described herein are contemplated and will be apparent to a skilled person having knowledge of this disclosure. Any of the various features and elements as disclosed herein may be combined with one or more other disclosed features and elements unless indicated to the contrary herein. Correspondingly, the subject matter as hereinafter claimed is intended to be broadly construed and interpreted, as including all such variations, modifications and alternative embodiments, within its scope and including equivalents of the claims.

### REFERENCES

[1] D. Qin, Y. Xia, G. M. Whitesides, Nat. Protoc. 2010, 5, 491.
[2] S. Lin, E. K. Lee, N. Nguyen, M. Khine, Lab Chip 2014, 14, 3475.
[3] A. Lal Das, R. Mukherjee, V. Katiyer, M. Kulkarni, A. Ghatak, A. Sharma, Adv. Mater. 2007, 19, 1943.
[4] H. Becker, C. Gärtner, Electrophoresis 2000, 21, 12.
[5] X.-M. Zhao, Y. Xia, O. J. A. Schueller, D. Qin, G. M. Whitesides, Sensors Actuators A Phys. 1998, 65, 209.
[6] A. Grimes, D. N. Breslauer, M. Long, J. Pegan, L. P. Lee, M. Khine, Lab Chip 2008, 8, 170.
[7] V. N. Goral, Y.-C. Hsieh, O. N. Petzold, R. A. Faris, P. K. Yuen, J. Micromechanics Microengineering 2011, 21, 017002.
[8] Y. Wang, J. Balowski, C. Phillips, R. Phillips, C. E. Sims, N. L. Allbritton, Lab Chip 2011, 11, 3089.
[9] M. H. Lee, M. D. Huntington, W. Zhou, J.-C. Yang, T. W. Odom, Nano Lett. 2011, 11, 311.
[10] O. Rahmanian, C.-F. Chen, D. L. DeVoe, Langmuir 2012, 28, 12923.
[11] W. Pfleging, M. Bruns, M. Przybylski, A. Welle, S. Wilson, in Proc. SPIE, Conf., Vol. 6880 (Eds: W. Pfleging, Y. Lu, K. Washio, W. Hoving, J. Amako), SPIE, Bellingham, Wash., USA 2008, p. 68800D.
[12] C.-S. Chen, D. N. Breslauer, J. I. Luna, A. Grimes, W.-C. Chin, L. P. Lee, M. Khine, Lab Chip 2008, 8, 622.
[13] X. Zhu, T. Cui, Sensors Actuators A Phys. 2013, 195, 21.
[14] H. Yabu, M. Shimomura, Polym. J. 2008, 40, 534.
[15] D. Dyer, S. Shreim, S. Jayadev, V. Lew, E. Botvinick, M. Khine, Appl. Phys. Lett. 2011, 99, 034102.
[16] C.-Y. Xue, W. Zhang, W. H. S. Choo, K.-L. Yang, Langmuir 2011, 27, 13410.
[17] D. Nguyen, D. Taylor, K. Qian, N. Norouzi, J. Rasmussen, S. Botzet, M. Lehmann, K. Halverson, M. Khine, Lab Chip 2010, 10, 1623.
[18] D. Ricci, P. C. Braga, in At. Force Microsc., Humana Press, New Jersey, 2004, pp. 25-38.
[19] D. O. H. Teare, C. Ton-That, R. H. Bradley, Surf. Interface Anal. 2000, 29, 276.
[20] P. Sarwate, A. Chakraborty, V. Garg, C. Luo, J. Micromechanics Microengineering 2014, 24, 115006.
[21] T.-Y. Lin, T. T. Pfeiffer, P. B. Lillehoj, RSC Adv. 2017, 7, 37374.
[22] D. O. H. Teare, N. Emmison, C. Ton-That, R. H. Bradley, Langmuir 2000, 16, 2818.
[23] D. Chanda, K. Shigeta, S. Gupta, T. Cain, A. Carlson, A. Mihi, A. J. Baca, G. R. Bogart, P. Braun, J. A. Rogers, Nat. Nanotechnol. 2011, 6, 402.
[24] Z. Xu, Y. Lin, Adv. Opt. Mater. 2019, 7, 1900379.

What is claimed is:

1. A method for patterning a substrate, the method comprising:
irradiating a pattern onto the substrate with ultraviolet light; and
heating the substrate, causing the substrate and the pattern to shrink in at least one dimension to form a miniaturized pattern on the substrate.

2. The method of claim 1, wherein irradiating the pattern onto the substrate comprises irradiating the substrate through a photomask with the pattern.

3. The method of claim 1, wherein irradiating the pattern onto the substrate comprises modulating the pattern onto the substrate using a programmable digital mirror device.

4. The method of claim 1, wherein irradiating the pattern onto the substrate comprises irradiating for a period of time such that photochemical reactions in the substrate result in physically forming the pattern onto the substrate.

5. The method of claim 1, wherein irradiating the pattern onto the substrate comprises irradiating with an intensity of ultraviolet radiation at the substrate such that photochemical reactions in the substrate result in physically forming the pattern onto the substrate.

6. The method of claim 1, wherein irradiating the pattern onto the substrate comprises irradiating with a proximity between a UV light source and a surface of the substrate such that photochemical reactions in the substrate result in physically forming the pattern onto the substrate.

7. The method of claim 1, wherein heating the substrate comprises heating the substrate for a period of time long enough to cause biaxial shrinkage of the substrate.

8. The method of claim 1, wherein the substrate comprises a shrinkable thermoplastic.

9. The method of claim 1, wherein irradiating the substrate comprises irradiating the substrate with a shortwave ultraviolet lamp.

10. The method of claim 1, comprising using the substrate and the miniaturized pattern in forming a microelectronic device, a microfluidic device, a micro-optic device, or a biomedical device, or a combination thereof.

11. A system for patterning a substrate, the system comprising:
an ultraviolet light source;
a heater; and
a controller configured for:
irradiating, using the ultraviolet light source, a pattern onto the substrate with ultraviolet light; and
heating the substrate using the heater, causing the substrate and the pattern to shrink in at least one dimension to form a miniaturized pattern on the substrate.

12. The system of claim 11, wherein irradiating the pattern onto the substrate comprises irradiating the substrate through a photomask with the pattern.

13. The system of claim 11, wherein irradiating the pattern onto the substrate comprises modulating the pattern onto the substrate using a programmable digital mirror device.

14. The system of claim 11, wherein irradiating the pattern onto the substrate comprises irradiating for a period of time such that photochemical reactions in the substrate result in physically forming the pattern onto the substrate.

15. The system of claim 11, wherein irradiating the pattern onto the substrate comprises irradiating with an intensity of ultraviolet radiation at the substrate such that photochemical reactions in the substrate result in physically forming the pattern onto the substrate.

16. The system of claim 11, wherein irradiating the pattern onto the substrate comprises irradiating with a proximity between a UV light source and a surface of the substrate such that photochemical reactions in the substrate result in physically forming the pattern onto the substrate.

17. The system of claim 11, wherein heating the substrate comprises heating the substrate for a period of time long enough to cause biaxial shrinkage of the substrate.

18. The system of claim 11, wherein the substrate comprises a shrinkable thermoplastic.

19. The system of claim 11, comprising an oven, and wherein heating the substrate comprises heating the substrate in the oven.

20. The system of claim 11, wherein the controller is configured for using the substrate and the miniaturized pattern in forming a microelectronic device, a microfluidic device, a micro-optic device, or a biomedical device, or a combination thereof.
